(19) United States
(12) Patent Application Publication
(10) Pub. No.: US 2024/0244757 A1
(43) Pub. Date: Jul. 18, 2024

(54) Method for preparing novel material layer structure of high-frequency circuit board and article thereof

(71) Applicant: LongKai LI, Chongqing (CN)

(72) Inventor: LongKai LI, Chongqing (CN)

(21) Appl. No.: 18/617,516

(22) Filed: Mar. 26, 2024

Related U.S. Application Data
(63) Continuation of application No. 17/753,127, filed on Feb. 18, 2022.

(51) Int. Cl. H05K 3/02; H05K 1/09; H05K 3/00; H05K 3/38

(52) U.S. Cl. CPC H05K 3/025; H05K 1/095; H05K 3/007; H05K 3/384; H05K 2201/0355

(57) ABSTRACT

The present invention discloses a method for preparing a novel material layer structure of a high-frequency circuit board, comprising the steps of: (1) coating a synthetic liquid TFP film on a cured PI film; (2) delivering the same to a tunnel oven for roasting in sections to form a semi-cured TFP film on a front surface of the cured PI film; and (3) hot pressing a copper foil on the semi-cured TFP film to obtain a novel single-sided material layer structure of a high-frequency circuit board. The present invention also discloses a novel material layer structure of a high-frequency circuit board prepared by performing the above-mentioned method. The prepared novel material layer structure of the high-frequency circuit board has the performance of high-speed transmission of high-frequency signals, and can adapt to the current high-frequency and high-speed trend from wireless network to terminal applications, especially for new 5G technology products. It can be used as a circuit board preparation material to manufacture a circuit board structure, such as a single-layer circuit board, a multi-layer flexible circuit board and a multi-layer soft-hard combined board, which brings great convenience to subsequent preparation for the circuit board and simplifies the process.

### CROSS REFERENCES TO RELATED APPLICATION

This application is a continuation of U.S. application Ser. No. 17/753,127, entitled “Method for preparing novel material layer structure of high-frequency circuit board and article thereof”, filed Feb. 18, 2022, and the entire contents of which are incorporated herein by reference.

### TECHNICAL FIELD

The present invention relates to the field of circuit boards, and more particularly, to a method for preparing a novel material layer structure of a high-frequency circuit board and an article thereof.

### BACKGROUND ART

At present, the communication frequency is overall high-frequency from the communication network to the terminal application. High-speed and large-capacity applications emerge endlessly. As wireless networks transition from 4G to 5G in recent years, network frequencies continue to rise. According to the 5G development roadmap shown in the relevant data, the future communication frequency will be promoted in two stages. The first phase aims to increase the communication frequency to 6 GHz by 2020, and the second phase to further increase it to 30-60 GHz by 2020. In the market application, the signal frequency of terminal antennas such as smart phones is increasing. There are more and more high-frequency applications, with more and more requirements for high speed and large capacity. To adapt to the current trend of high-frequency and high speed from wireless networks to terminal applications, soft boards, as antennas and transmission lines in terminal devices, will also be subject to technological upgrading.

The conventional soft board has a multi-layer structure composed of a copper foil, an insulating substrate, a cover layer and the like, with the copper foil as a conductor circuit material, a PI film as a circuit insulating substrate, and a PI film and an epoxy adhesive as a cover layer for protecting and isolating a circuit, which are processed into a PI soft board by a certain process. Since the properties of the insulating substrate determine the final physical and electrical properties of the soft board, the soft board needs to use substrates with various performance characteristics in order to adapt to different application scenarios and functions. Polyimide (PI) is the most widely used soft board substrate at present. However, due to the larger dielectric constant and loss factor, higher moisture absorption and poor reliability of PI substrate, the high-frequency transmission loss of PI soft board is serious and its structural characteristics are poor, which cannot adapt to the current high-frequency and high-speed trend. Therefore, with the emergence of new 5G technology products, the signal transmission frequency and speed of existing circuit boards have been difficult to meet the requirements of 5G technology products.

Meanwhile, in the preparation technique, there are many problems in the traditional multi-layer flexible circuit board or multilayer combination of hard and soft boards, such as more process flows, complex manufacturing process, and higher power consumption and signal transmission loss in circuit board performance.

### SUMMARY OF THE INVENTION

In view of the above-mentioned deficiencies, it is an object of the present invention to provide a method for preparing a novel material layer structure of a high-frequency circuit board and an article thereof. The prepared novel material layer structure of the high-frequency circuit board has the performance of high-speed transmission of high-frequency signals, and can adapt to the current high-frequency and high-speed trend from wireless network to terminal applications, especially for new 5G technology products. The novel material layer structure of the circuit board, as an integral structure, can be used as a manufacturing material of the circuit board in a subsequent manufacturing process of the circuit board to manufacture a circuit board structure such as a single-layer circuit board, a multi-layer flexible circuit board and a multi-layer soft-hard combined board, which brings great convenience to the subsequent manufacturing of the circuit board, simplifies the manufacturing process, accelerates the manufacturing speed of the circuit board, and reduces production costs.

The technical solution adopted by the invention for achieving the above purpose is as follows.

A method for preparing a novel material layer structure of a high-frequency circuit board is characterized by comprising the steps of:
(1) coating a layer of synthetic liquid TFP film on a front surface of a cured PI film;
(2) delivering the whole of the cured PI film coated with the synthetic liquid TFP film into a tunnel oven, and successively passing the same through a plurality of sections of heating and roasting zones in the tunnel oven at a speed of 0.5-20 m/s for roasting in sections, so as to form a semi-cured TFP film on the front surface of the cured PI film;
(3) hot pressing a copper foil on the semi-cured TFP film to obtain a novel single-sided material layer structure of a high-frequency circuit board.

As a further improvement of the present invention, the step (1) further comprises the steps of: coating a layer of synthetic liquid TFP film on a back surface of the cured PI film; after the step (2), forming a semi-cured TFP film on both the front surface and the back surface of the cured PI film; after the step (3), obtaining a novel double-sided material layer structure of a high-frequency circuit board.

As a further improvement of the present invention, in the step (2), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

As a further improvement of the present invention, in the step (3), the cured PI film with the semi-cured TFP film is placed on a lower support plate of a laminating machine, and a copper foil is placed on the semi-cured TFP film; the laminating machine is then started, and the semi-cured TFP film is cured and pressed together with the copper foil by hot pressing at a temperature of 60° C.-500° C. and a pressure of 80-500 psi for 10-60 minutes.

As a further improvement of the present invention, in the step (1), a colored filler is added to at least one of the cured PI film and the synthetic liquid TFP film.

As a further improvement of the invention, the colored filler is a carbide.

A novel material layer structure of a high-frequency circuit board prepared by performing the method above is characterized by comprising a cured PI film, an upper semi-cured TFP film coated on the front surface of the cured PI film, and an upper copper foil layer laminated on the upper semi-cured TFP film.

As a further improvement of the present invention, a lower semi-cured TFP film is coated on the back surface of the cured PI film; and a lower copper foil layer is laminated on a lower surface of the lower semi-cured TFP film.

As a further improvement of the present invention, at least one of the cured PI film and the upper half-cured TFP film is a colored layer.

The invention has the following beneficial effects.
(1) A novel material layer structure of the high-frequency circuit board is prepared by using the coating process. As an integral structure, this novel material layer structure of the high-frequency circuit board can be used as a circuit board manufacturing material in subsequent circuit board manufacturing processes; and a circuit board structure such as a single-layer circuit board, a multi-layer flexible circuit board and a multi-layer soft-hard combined board can be manufactured by subsequent direct hot-pressing processes with other materials or circuit boards, which brings great convenience for subsequent circuit board manufacturing. Therefore, it can simplify the manufacturing process, accelerate the manufacturing speed of the circuit board, shorten the processing time of the product, improve the processing capacity of the process and reduce the production cost. Furthermore, the product structure is optimized and the product performance is improved.
(2) The cured PI film is used as a substrate for preparing the novel material layer structure of high-frequency circuit board, and the semi-cured TFP film is used as a base material for forming the circuit, which can not only improve the stability and dimensional stability of the overall performance of the circuit board, but also have high-frequency characteristics. It can transmit high-frequency signals, speed up the transmission speed of high-frequency signals, and achieve high-speed transmission of high-frequency signals, with low power consumption and high-frequency signal transmission loss, improving the signal transmission performance of the circuit board. It can adapt to the current high-frequency and high-speed trend from wireless networks to terminal applications, especially for new 5G technology products.

The above is an overview of the technical scheme of the invention. The following is a further explanation of the invention in combination with the attached drawings and specific implementations.

### BRIEF DESCRIPTION OF THE DRAWINGS

FIG. 1 is an overall sectional view of a novel single-sided material layer structure of a high-frequency circuit board according to Embodiment 1 of the present invention;

FIG. 2 is an overall sectional view of a novel double-sided material layer structure of a high-frequency circuit board according to Embodiment 2 of the present invention.

### DETAILED DESCRIPTION OF THE INVENTION

In order to further explain the technical means and effects of the present invention for achieving the intended purpose, the following detailed description of the embodiments of the present invention will be made with reference to the accompanying drawings and preferred embodiments.

### Embodiment 1

The invention provides a method for preparing a novel material layer structure of a high-frequency circuit board, comprising the steps of:
(1) coating a layer of synthetic liquid TFP film on a front surface of a cured PI film;
(2) delivering the whole of the cured PI film coated with the synthetic liquid TFP film into a tunnel oven, and successively passing the same through a plurality of sections of heating and roasting zones in the tunnel oven at a speed of 0.5-20 m/s for roasting in sections, so as to form a semi-cured TFP film on the front surface of the cured PI film;
(3) hot pressing a copper foil on the semi-cured TFP film to obtain a novel single-sided material layer structure of a high-frequency circuit board.

In the step (2), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

In the step (3), the cured PI film with the semi-cured TFP film is placed on a lower support plate of a laminating machine, and a copper foil is placed on the semi-cured TFP film;

the laminating machine is then started, and the semi-cured TFP film is cured and pressed together with the copper foil by hot pressing at a temperature of 60° C.-500° C. and a pressure of 80-500 psi for 10-60 minutes.

The novel material layer structure of the high-frequency circuit board prepared in this embodiment can form a single-layer circuit board in a later process as long as a circuit is formed on a copper foil, and then a layer of PI film and a layer of adhesive are successively hot-pressed on the copper foil on which the circuit is formed.

Meanwhile, after forming a circuit on the copper foil, the novel material layer structure of the high-frequency circuit board prepared in this embodiment is laminated in multiple groups to form a multi-layer flexible circuit board.

Meanwhile, a multi-layer soft-hard combining board can be formed by integrally hot-pressing the novel material layer structure of the high-frequency circuit board onto a glass fabric with an adhesive on both sides, hot-pressing a copper foil on one side of the glass fabric away from the material layer structure of the circuit board, and then forming a circuit on the copper foil.

Of course, the novel material layer structure of the high-frequency circuit board can also be directly hot-pressed onto other circuit boards to form other circuit board structures.

In this embodiment, the semi-cured TFP film is used as a base material for forming the circuit. TFP is a unique thermoplastic material with the following properties compared to conventional PI materials.
(1) Low dielectric constant: a low Dk value, the Dk value being specifically 2.55; while the Dk value of conventional PI is 3.2; therefore, the signal propagation speed is faster, the thickness is thinner, and the spacing is closer; and the power processing capacity is higher.
(2) Ultra-low material loss.
(3) Ultrahigh temperature performance, withstanding a high temperature of 300° C.
(4) The moisture absorption rate is relatively low.

Therefore, using the semi-cured TFP film as the substrate required for preparing the novel material layer structure of the circuit board in the embodiment can not only improve the stability and dimensional stability of the overall performance of the circuit board, but also can give high-frequency characteristics, transmit high-frequency signals, accelerate the transmission speed of high-frequency signals and reduce power consumption and high-frequency signal transmission loss to improve the signal transmission performance of the circuit board, which adapt to the current high-frequency and high-speed trend from wireless networks to terminal applications, especially suitable for new 5G technology products.

Meanwhile, the dimensional stability of the novel material layer structure of the high-frequency circuit board can be further improved by using the cured PI film as the substrate.

In the step (1), the cured PI film and the synthetic liquid TFP film may have the color of the material itself or may have a transparent color.

Of course, a colored filler may also be added to at least one of the cured PI film and the synthetic liquid TFP film. Specifically, the colored filler can be a carbide or other colored filler. Black color can appear when the colored filler is added to the cured PI film and the synthetic liquid TFP film. Whether the novel material layer structure of the high-frequency circuit board prepared in this embodiment is made into a single-layer circuit board, a multi-layer flexible circuit board, or a multi-layer soft-hard combined board, the black cured PI film and the synthetic liquid TFP film have a shielding effect on the circuit, which can prevent the internal circuit from being exposed, and prevent the external person from seeing the internal circuit from the outside to play the role of concealing and protecting the circuit on the circuit board; meanwhile, it plays the role of masking defects for the circuit board or circuit with impurities or defects.

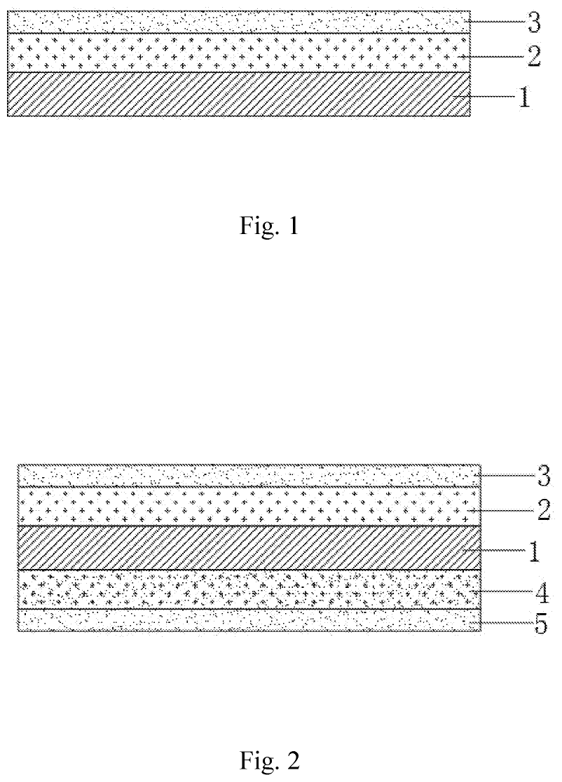

This embodiment also provides a novel material layer structure of a high-frequency circuit board prepared by performing the above-mentioned method, as shown in FIG. 1, including a cured PI film 1, an upper semi-cured TFP film 2 coated on a front surface of the cured PI film 1, and an upper copper foil layer 3 laminated on the upper semi-cured TFP film 2 to form a novel single-sided material layer structure of a high-frequency circuit board. Specifically, after the upper copper foil layer 3 is laminated to the upper semi-cured TFP film 2, the upper semi-cured TFP film 2 is cured and laminated to the upper copper foil layer 3.

In this embodiment, at least one of the cured PI film 1 and the upper semi-cured TFP film 2 is a colored layer. The colored layer can be specifically black, which plays the role of shielding, protection, masking and so on for the internal circuit.

The cured PI film is used as a substrate for preparing the novel material layer structure of high-frequency circuit board in the embodiment, and the semi-cured TFP film is used as a base material for forming the circuit, which can not only improve the stability and dimensional stability of the overall performance of the circuit board, but also have high-frequency characteristics. It can transmit high-frequency signals, and speed up the transmission speed of high-frequency signals, with low power consumption and high-frequency signal transmission loss, improving the signal transmission performance of the circuit board. It can adapt to the current high-frequency and high-speed trend from wireless networks to terminal applications, especially for new 5G technology products.

### Embodiment 2

The main differences between this embodiment and Embodiment 1 are as follows.

The step (1) further comprises the steps of: coating a layer of synthetic liquid TFP film on a back surface of a cured PI film; after the step (2), forming a semi-cured TFP film on both the front surface and the back surface of the cured PI film; after the step (3), obtaining a novel double-sided material layer structure of a high-frequency circuit board.

Therefore, a novel double-sided material layer structure of a high-frequency circuit board can be prepared by the above-mentioned method. As shown in FIG. 2, a lower semi-cured TFP film 4 is coated on the back surface of the cured PI film 1; and a lower copper foil layer 5 is laminated on a lower surface of the lower semi-cured TFP film 4 to form the novel double-sided material layer structure of the high-frequency circuit board. Specifically, after the lower copper foil layer 5 is laminated to the lower semi-cured TFP film 4, the lower semi-cured TFP film 4 is cured and laminated to the lower copper foil layer 5.

In the description above, only the preferred embodiments of the present invention has been described, and the technical scope of the present invention is not limited in any way. Therefore, other structures obtained by adopting the same or similar technical features as those of the above embodiments of the present invention are within the scope of the present invention.

1. A method for preparing a novel material layer structure of a high-frequency circuit board, characterized by comprising the steps of:
(1) coating a layer of synthetic liquid TFP film on a front surface of a cured PI film;
(2) delivering the whole of the cured PI film coated with the synthetic liquid TFP film into a tunnel oven, and successively passing the same through a plurality of sections of heating and roasting zones in the tunnel oven at a speed of 0.5-20 m/s for roasting in sections, so as to form a semi-cured TFP film on the front surface of the cured PI film;
(3) hot pressing a copper foil on the semi-cured TFP film to obtain a novel single-sided material layer structure of a high-frequency circuit board.

2. The method for preparing a novel material layer structure of a high-frequency circuit board according to claim 1, characterized in that the step (1) further comprises the steps of: coating a layer of synthetic liquid TFP film on a back surface of the cured PI film; after the step (2), forming a semi-cured TFP film on both the front surface and the back surface of the cured PI film; after the step (3), obtaining a novel double-sided material layer structure of a high-frequency circuit board.

3. The method for preparing a novel material layer structure of a high-frequency circuit board according to claim 1, characterized in that in the step (2), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

4. The method for preparing a novel material layer structure of a high-frequency circuit board according to claim 1, characterized in that in the step (3), the cured PI film with the semi-cured TFP film is placed on a lower support plate of a laminating machine, and a copper foil is placed on the semi-cured TFP film; the laminating machine is then started, and the semi-cured TFP film is cured and pressed together with the copper foil by hot pressing at a temperature of 60° C.-500° C. and a pressure of 80-500 psi for 10-60 minutes.

5. The method for preparing a novel material layer structure of a high-frequency circuit board according to claim 1, characterized in that in the step (1), a colored filler is added to at least one of the cured PI film and the synthetic liquid TFP film.

6. The method for preparing a novel material layer structure of a high-frequency circuit board according to claim 5, characterized in that the colored filler is a carbide.

7. A novel material layer structure of a high-frequency circuit board prepared by performing the method according to claim 1, characterized by comprising a cured PI film, an upper semi-cured TFP film coated on the front surface of the cured PI film, and an upper copper foil layer laminated on the upper semi-cured TFP film.

8. The novel material layer structure of a high-frequency circuit board according to claim 7, characterized in that a lower semi-cured TFP film is coated on the back surface of the cured PI film; and a lower copper foil layer is laminated on a lower surface of the lower semi-cured TFP film.

9. The novel material layer structure of a high-frequency circuit board according to claim 7, characterized in that at least one of the cured PI film and the upper half-cured TFP film is a colored layer.

10. The novel material layer structure of a high-frequency circuit board according to claim 7, characterized in that the novel material layer structure is prepared by performing the method according to claim 2.

11. The novel material layer structure of a high-frequency circuit board according to claim 7, characterized in that the novel material layer structure is prepared by performing the method according to claim 3.

12. The novel material layer structure of a high-frequency circuit board according to claim 7, characterized in that the novel material layer structure is prepared by performing the method according to claim 4.

13. The novel material layer structure of a high-frequency circuit board according to claim 7, characterized in that the novel material layer structure is prepared by performing the method according to claim 5.

14. The novel material layer structure of a high-frequency circuit board according to claim 7, characterized in that the novel material layer structure is prepared by performing the method according to claim 6.
